(19) United States
(12) Patent Application Publication
(10) Pub. No.: US 2004/0027205 A1
(43) Pub. Date: Feb. 12, 2004

(54) Local oscillator apparatus for low-noise generation of arbitrary frequencies

(76) Inventors: Josef Ludvik Fikart, Port Moody (CA); Sasa T. Trajkovic, Burnaby (CA); Serguei Khoudiakov, Surrey (CA)

Correspondence Address: Vermette & Co., Box 40 Granville Square, 200 Granville Street, Suite 230, Vancouver, BC, V6C 1S4, CA

(21) Appl. No.: 10/212,774

(22) Filed: Aug. 7, 2002

(51) Int. Cl. H03L 7/00

(52) U.S. Cl. 331/11

(57) ABSTRACT

A method and apparatus are hereby presented for the purpose of supplying local oscillator frequencies used for upconversion and downconversion of electronic signals for transmitters or receivers. The apparatus contains a voltage controlled oscillator for generating the signal used for upconversion or downconversion, a reference signal, a second oscillator or source locked to the reference signal which is used in a heterodyne loop for the purpose of enabling any arbitrary frequency to be generated, a sampling phase detector which is part of the heterodyne loop, and dividers for dividing the reference signal as well as the heterodyne output of the sampling phase detector. The purpose of the heterodyne loop is twofold. By reducing the frequency by means of heterodyne action the divider ratio can be kept small, thus reducing the phase noise. Also, the heterodyne technique permits the synthesis of any arbitrary frequency, through the choice of the appropriate heterodyne frequency.

### FIELD

The present invention relates generally to a phase locked loop (PLL) for use in a local oscillator, and more particularly to a PLL wherein a heterodyne technique is used in conjunction with a sampling phase detector.

### BACKGROUND OF THE INVENTION

High frequency communication systems such as transmitters or receivers require highly stable local oscillator signals. These are used in transmitters for the purpose of upconverting the signal generated by a modulator to the desired RF frequency for connection to an antenna. These devices are also used in receivers for downconverting the received RF signal to an intermediate frequency, where amplification and further processing can be implemented.

Prior art local oscillators commonly have a PLL, which includes a phase detector having an output coupled through a loop filter to control the frequency of a Voltage Controlled Oscillator (VCO). The output of the VCO is then fed back through a divide-by-N circuit to the first input of the phase detector. A constant frequency reference signal is applied to a second input of the phase detector by a highly stable reference oscillator, typically operating at a low frequency. A divide-by-M circuit is used to reduce the frequency of the reference signal to the same as that of the VCO. The frequency of the VCO output signal is changed in finite steps by changing the ratio “N” of the divide-by-N circuit in a pre-determined manner.

Standard forms of synthesizers use division by whole numbers for the two signals brought to the phase detector for comparison. Depending on the output frequency to be synthesized, it is often necessary to use high division ratios that result in a very low comparison frequency at the phase detector. When such synthesizers are used to control oscillators that are required to hop from one frequency to another with a certain minimum “step size”, the comparison frequency must be equal to, or lower than, the minimum step size. Since the synthesizer output contains spurious signals at the comparison frequency (in addition to the desired slow, almost DC, component for oscillator correction), the local oscillator must additionally employ suitable low-pass filters to prevent these undesired signals from reaching the control element (i.e. the varactor) of the VCO. When the step size is small and therefore the comparison frequency is low, the filters are narrowband, which in turn results in slow switching speeds when the synthesizer is instructed to change the oscillator output frequency.

In cases where high resolution is required, both the reference signal and the VCO frequency must be divided to a small fraction of the reference signal, at which frequency the comparison between the two is made for correction proposes. This is necessary since the VCO output frequency is not a simple multiple of the reference signal frequency.

In the prior art the division and phase comparison is normally performed in an IC containing all the necessary circuitry. The disadvantage of the prior art is that the phase noise performance of the local oscillator is degraded as a result of the synthesizer noise, which is effectively magnified by the ratio of the VCO output frequency and the reference signal frequency.

Alternatively, in the prior art means have been proposed for reducing the effects of this unwanted noise. These means consist of reducing the frequency of the VCO by heterodyne means prior to division. This greatly reduces the ratio of “N”, and thus reduces the unwanted noise. However, this results in the local oscillator being more complex and expensive.

A further technique, usually employed in receivers, consists of using a Sampling Phase Detector (SPD) which consists of a high order multiplier and a mixer. In the prior art, a SPD has been used in those instances where the local oscillator output is a multiple of yet another multiple of the reference signal. The output of the mixer is then at DC, and can be used directly as the input to the corrective element (eg. a variable capacitance) in the VCO. This technique does not use an active phase detector or synthesizer and thus avoids the effect of synthesizer noise at the local oscillator output. However, the frequencies that can be synthesized are restricted due to the fact that the output from the SPD must be at DC.

Accordingly, it is an object of this invention to provide an improved local oscillator for use in communications systems which provides for the generation of any arbitrary frequency while keeping the phase noise low.

### SUMMARY OF THE INVENTION

These and other objects have been realized in a local oscillator whose frequency can be changed within a predetermined frequency range, comprising a voltage controlled oscillator (VCO), a reference oscillator, a circuit for phase-comparison of the output signals from both the VCO and reference oscillator, a second stable frequency source, a bandpass filter supplied with the output signal from the phase-comparison circuit, which supplies a signal to the VCO to phase-lock the VCO with the reference signal, and a circuit for obtaining a sample of the frequency of the VCO.

According to the local oscillator of the present invention, any desired frequency can be synthesized independently of the frequency of the reference signal.

The phase comparison circuit is a sampling phase detector (SPD) used with a heterodyne loop. The chief advance in the art provided by this invention resides in the manner in which a heterodyne loop, is used to reduce the frequency of the signal to be stabilized prior to comparison in a phase detector.

### BRIEF DESCRIPTION OF THE DRAWINGS

Other objects, features, aspects and advantages of the present invention will become apparent to those of ordinary skill from the following detailed description of the invention taken in conjunction with the accompanying drawing, in which:

FIG. 1 is a block diagram of the local oscillator of the present invention.

### DETAILED DESCRIPTION OF THE INVENTION

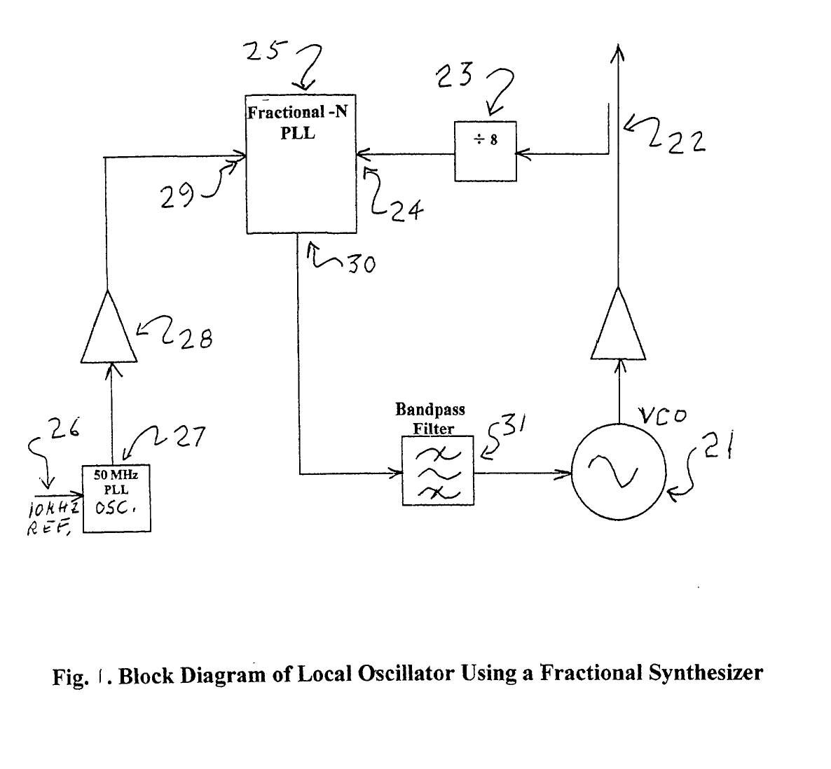

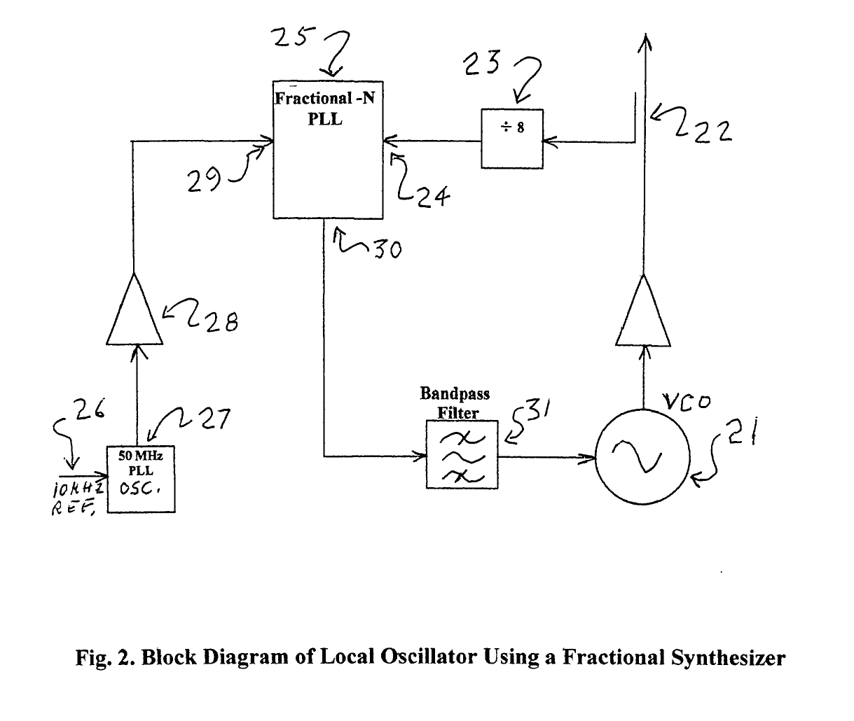

Referring to FIG. 1, the local oscillator circuit of the present invention includes a voltage-controlled oscillator (VCO) 1, which is used to produce the desired output signal of the local oscillator. A sample of the output from VCO 1 is obtained via coupler 2. The sample obtained from coupler 2 is applied to the high frequency port 11 of the sampling phase detector (SPD) 3.

A highly stable reference signal source 4 is used to stabilize a PLL oscillator 5, which acts as a second stable frequency source. The output from the PLL oscillator 5 is amplified in amplifier 6. The output of the amplifier 6 is applied to the low frequency input port 12 of the SPD 3. Within the SPD 3, the input signal from the amplifier 6 is used to generate a comb of frequencies, with each frequency being a multiple of the frequency of the PLL oscillator 5. The frequency in this comb of frequencies which is closest to the output frequency of the VCO 1 will mix with the output frequency of the VCO 1, to produce an intermediate frequency output at port 13 of the SPD 3.

The intermediate frequency output signal output from port 13 of the SPD 3 is divided by a factor of “N” in the divider 7. A portion of the refence signal from highly stable reference signal source 4 is divided in divider 8 by a ratio “M”. The output signals of divider 7 and divider 8 are applied to a phase detector 9. Phase detector 9 compares the phase of the two signals from divider 7 and divider 8, and produces an output signal based on the phase difference. This signal is then filtered by bandpass filter 10. The output from bandpass filter 10 is applied to VCO 1 as a frequency-controlling signal. Thus, for any given output frequency of the VCO 1, the VCO 1 is locked to a stable reference which is determined by the frequency of the PLL oscillator 5 and the ratios “N” and “M” of the dividers 7 and 8.

The PLL oscillator 5 is merely one example of a number of frequency multiplier circuits that can be used to raise the frequency of the signal from highly stable reference signal source 4. For example, in an alternate embodiment, the PLL oscillator 5 could be replaced with a multiplier driven by the reference signal source 4.

The present invention can be described with reference to an illustrative embodiment, in which a local oscillator is required to generate a frequency of 9.5166666 GHz. The local oscillator of the illustrative embodiment comprises a VCO 1, containing a varactor, which enables the variation of the VCO output frequency by means of an electrically controlled variable capacitance. A small sample of the VCO signal is fed to the high frequency port 11 of SPD 3. A second stable frequency, of 50 MHz, is generated by PLL oscillator 5, which is stabilized by the signal from the 10 MHz highly stable reference signal source 4. Alternatively, the 50 MHz signal could be generated by multiplying the 10 MHz signal from the highly stable reference signal source 4 by a factor of 5. The 50 MHz signal is applied to the low frequency input port 12 of the SPD 3. Within the SPD 3 the 50 MHz signal is multiplied to create a comb of frequencies, each separated by 50 MHz. The multiple of 50 MHZ closest in frequency to the output of the VCO is then mixed with the sample of the output of the VCO to produce an intermediate frequency output at port 13. In this example, the multiple of 50 MHz closest to 9.5166666 GHz is 9.5000 GHz. Thus, the intermediate frequency output from the SPD 3 is 16.6666 MHz. The intermediate frequency output is then divided by a divider 7 with the ratio “N”. In the present illustrative example, N is chosen to be 5, thus the output of the divider 7 is 3.3333 MHz. In addition, the 10 MHz highly stable reference signal is divided in a divider 8 by the factor “M”; in this example “M” is chosen to be 3. Thus the output of the divider 8 is 3.3333 MHz. The two signals, the outputs of the dividers 7 and 8, which are now nominally equivalent in frequency, are applied to the inputs of a phase detector 9. The difference in frequency between the two signals inputted to the phase detector 9 will result in an output signal, which acts as an error voltage, which is filtered by bandpass filter 10 and used to control the output frequency of the VCO 1. By this means, a stabilized 9.5166666 GHz local oscillator signal is obtained. The low ratio between VCO output frequency and the comparison frequency results in low local oscillator phase noise.

It will be appreciated that the particular type or construction of the various components constituting the local oscillator system are not critical or limiting to either the scope or practice of the present invention. As such, since the hardware implementation of these various components of the present invention will be easily and readily accessible to those skilled in the art of communications systems, these various components have only been referred to generically in the description of the present invention. In this regard, it will become apparent that the novelty of the present invention resides primarily in a unique combination and architectural configuration of these various components in order to generate an arbitrary set of stabilized local oscillator signals with a phase noise lower that that achievable by the prior art.

The aforementioned embodiments should be regarded as illustrative rather than restrictive, and it should be appreciated that variations may be made other than those discussed, by workers of ordinary skill in the art without departing from the scope of the present invention as defined by the following claims:

What is claimed is:

1. A variable frequency local oscillator, comprising:
a) a voltage controlled oscillator (VCO);
b) a reference signal source operative to produce a reference signal;
c) a second signal source coupled to said reference operative to produce a second reference signal which is a desired multiple of said reference signal;
d) a first phase detector circuit having a first input port coupled to said second signal source, a second input port coupled to said VCO, said first phase detector circuit operative to generate a comb of frequencies from said second reference signal and to mix said output of said VCO with a frequency from said comb of frequencies which is closest in frequency to said output of said VCO, to produce an intermediate frequency output at a third port;
e) a divide by M circuit, wherein M is an integer, having an input coupled to said reference signal source, said divide by M circuit operative to divide a frequency of said reference signal by a factor of M;
f) a divide by N circuit, wherein N is an integer, having an input coupled to said third port of said first phase detector circuit, said divide by N circuit operative to divide a frequency of said intermediate frequency output by a factor of N;
g) a second phase detector coupled to outputs of said divide by M and divide by N circuits and operative to produce an error voltage on its output based on a difference between outputs of said divide by M and divide by N circuits;
wherein said error voltage is applied to an input of said VCO to control a frequency of said output of said VCO.

2. A variable frequency local oscillator according to claim 1, wherein said second signal source is a phase locked loop oscillator.

3. A variable frequency local oscillator according to claim 1, further comprising a bandpass filter having an input coupled to said output of said second phase detector and an output coupled to an input of said VCO, said bandpass filter operative to filter said error voltage.

4. A variable frequency local oscillator according to claim 1, further comprising an amplifier having an input coupled to said second signal source and an output coupled to said first input port of said first phase detector, wherein said amplifier is operative to amplify said output of said second signal source.

5. A variable frequency local oscillator according to claim 1, further comprising an amplifier having an input coupled to said VCO, wherein said amplifier is operative to amplify said output of said VCO.

6. A variable frequency local oscillator according to claim 1, wherein said VCO comprises a varactor.

7. A variable frequency local oscillator according to claim 1, wherein said frequency of said signal output by said first phase detector is represented by a variable fₒ, where fₒ is determined by the following equation, fₒ=fₗₒ−qfₕ, where fₗₒ is said frequency of said output of said voltage controlled oscillator and fₕ is a frequency of said second reference signal, and q is an integer representation of an harmonic number of an harmonic of said second reference signal, which lies closest in frequency to said frequency of said output of said voltage controlled oscillator.

8. A method of generating a stabilized variable frequency signal with low phase noise, comprising:
a) generating a variable frequency output signal;
b) generating a highly stable reference signal;
c) generating a second reference signal having a frequency that is a multiple of said highly stable reference signal;
d) generating a comb of signals from said second reference signal, each one of said signals in said comb having a frequency that is a multiple of said frequency of said second reference signal;
e) generating an intermediate frequency signal by mixing said variable frequency output signal with one of said signals in said comb having a frequency that is nearest to a frequency of said variable frequency output signal;
f) generating a divide-by-N signal by dividing a frequency of said intermediate frequency signal by an integer N;
g) generating a divide-by-M signal by dividing a frequency of said highly stable reference signal by an integer M;
h) generating an error voltage from a difference between said divide-by-N signal and said divide-by-M signal; and
i) varying a frequency of said variable frequency output signal in response to said error voltage.

9. A method according to claim 7, wherein said error voltage is filtered.

10. A method according to claim 7, wherein said second reference signal is amplified prior to generating said comb of signals.

11. A method according to claim 7, wherein said variable frequency output signal is amplified prior to mixing with said comb signals.

12. A method according to claim 7, wherein said second reference signal is generated using a phase locked loop.

13. A method according to claim 7, wherein said variable frequency output signal is generated using a voltage controlled oscillator.
